(19) United States
(12) Patent Application Publication
(10) Pub. No.: US 2015/0313026 A1
(43) Pub. Date: Oct. 29, 2015

(54) Support Device for Tablet Personal Computer

(71) Applicant: Tsung-Yao Yu, Taichung City (TW)

(72) Inventor: Tsung-Yao Yu, Taichung City (TW)

(21) Appl. No.: 14/264,130

(22) Filed: Apr. 29, 2014

(51) Int. Cl. H05K 5/02; G06F 1/16

(52) U.S. Cl. CPC H05K 5/0204; G06F 1/1626

(57) ABSTRACT

A support device for a tablet personal computer includes a base unit, a width adjustment unit, and a height adjustment unit. Thus, when a tablet personal computer is placed on the base unit, the width adjustment unit is adjusted freely to fit the width of the tablet personal computer, and the height adjustment unit is adjusted freely to fit the height of the tablet personal computer, so that the support device is available for tablet personal computers of different sizes.

### BACKGROUND OF THE INVENTION

1. Field of the Invention

The present invention relates to a support device and, more particularly, to a support device for a tablet personal computer (PC).

2. Description of the Related Art

A conventional support rack is used to place and support a tablet personal computer in an inclined manner to facilitate the user operating the tablet personal computer. However, the conventional support rack has a fixed size so that it cannot exactly fit the width and height of tablet personal computers of different sizes, thereby limiting the versatility of the conventional support rack. In addition, the conventional support rack cannot clamp the tablet personal computer so that the tablet personal computer easily falls down inadvertently.

### BRIEF SUMMARY OF THE INVENTION

In accordance with the present invention, there is provided a support device for a tablet personal computer, comprising a base unit, and a width adjustment unit. The width adjustment unit includes two supporting modules mounted on the base unit, and a width adjustment module mounted on the base unit. The supporting modules are respectively extended rightward and leftward from the base unit. Each of the supporting modules includes a toothed rack extended through the base unit, and a holder mounted on an outer end of the toothed rack. The width adjustment module includes a width adjustment gear arranged between the toothed racks of the supporting modules and respectively meshing with the toothed racks of the supporting modules. The width adjustment gear is rotatable to drive the supporting modules simultaneously to approach each other or to space from each other.

The toothed racks of the supporting modules are arranged in a stagger manner and are located opposite to each other. The toothed racks of the supporting modules are respectively extended rightward and leftward from the base unit. Each of the supporting modules further includes a guide track located opposite to the toothed rack. The guide track of each of the supporting modules is extended from the holder toward the base unit and extended through the base unit. The width adjustment gear has two opposite sides respectively abutting the toothed rack and the guide track of each of the supporting modules.

The width adjustment module further includes a width adjustment fastener. The width adjustment fastener has an abutting portion mounted on the width adjustment gear, and a driving handle mounted on the abutting portion. The driving handle is driven to rotate about an axis thereof so as to drive and rotate the width adjustment gear.

The abutting portion has a projection. Thus, when the driving handle is driven and pressed downward to approach the base unit, the projection presses the base unit to position the width adjustment fastener.

The support device further comprises a height adjustment unit. The height adjustment unit includes a lower supporting module mounted on the base unit and extended downward, and a height adjustment module mounted on the base unit. The lower supporting module includes a lower toothed rack extended through the base unit and extended downward, and a lower holder mounted on a lower end of the lower toothed rack. The height adjustment module includes a height adjustment gear meshing with the lower toothed rack of the lower supporting module. The height adjustment gear is rotatable to drive the lower supporting module to approach the base unit or to space from the base unit.

The lower supporting module further includes a lower guide track located opposite to the lower toothed rack. The lower guide track of the lower supporting module is extended from the lower holder toward the base unit and extended through the base unit. The height adjustment gear has two opposite sides respectively abutting the lower toothed rack and the lower guide track of the lower supporting module.

The height adjustment module further includes a height adjustment fastener. The height adjustment fastener has an abutting portion mounted on the height adjustment gear, and a driving handle mounted on the abutting portion. The driving handle is driven to rotate about an axis thereof so as to drive and rotate the height adjustment gear.

The abutting portion has a projection. Thus, when the driving handle is driven and pressed downward to approach the base unit, the projection presses the base unit to position the height adjustment fastener.

Preferably, the lower holder of the lower supporting module has a middle portion provided with an opening.

The base unit includes a main body, and a connecting member. The connecting member extends rearward from a rear side of the main body and has a distal end formed with a spherical connecting head.

According to the primary advantage of the present invention, the width adjustment gear meshes with the toothed racks so that when the width adjustment gear is rotated, the supporting modules are driven by the width adjustment gear simultaneously to approach each other or to space from each other, so as to adjust the required width rapidly.

According to another advantage of the present invention, the height adjustment gear meshes with the lower toothed rack so that when the height adjustment gear is rotated, the lower supporting module is driven by the height adjustment gear to approach the base unit or to space from the base unit, so as to adjust the required height rapidly.

According to a further advantage of the present invention, the width adjustment unit is adjusted freely to fit the width of the tablet personal computer, and the height adjustment unit is adjusted freely to fit the height of the tablet personal computer, so that the support device is available for tablet personal computers of different sizes.

According to a further advantage of the present invention, the tablet personal computer is clamped between the holders of the supporting modules and the lower holder of the lower supporting module by positioning of the width adjustment fastener and the height adjustment fastener.

According to a further advantage of the present invention, the lower holder of the lower supporting module is provided with an opening to prevent the slots of the tablet personal computer from being hindered or blocked.

Further benefits and advantages of the present invention will become apparent after a careful reading of the detailed description with appropriate reference to the accompanying drawings.

### BRIEF DESCRIPTION OF THE SEVERAL VIEWS OF THE DRAWING(S)

FIG. 1 is a perspective view of a support device for a tablet personal computer in accordance with the preferred embodiment of the present invention.

FIG. 2 is a partially perspective view of the support device as shown in FIG. 1.

FIG. 3 is a side cross-sectional operational view of the support device as shown in FIG. 1.

FIG. 4 is a schematic bottom operational view of the support device as shown in FIG. 1.

FIG. 5 is a schematic bottom operational view of the support device as shown in FIG. 1.

FIG. 6 is a schematic side operational view of the support device as shown in FIG. 1.

### DETAILED DESCRIPTION OF THE INVENTION

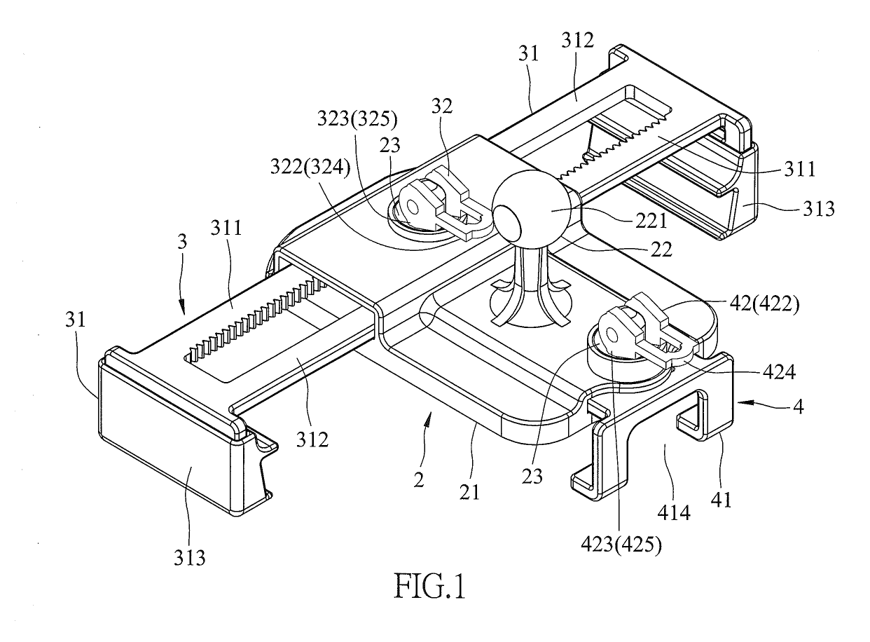

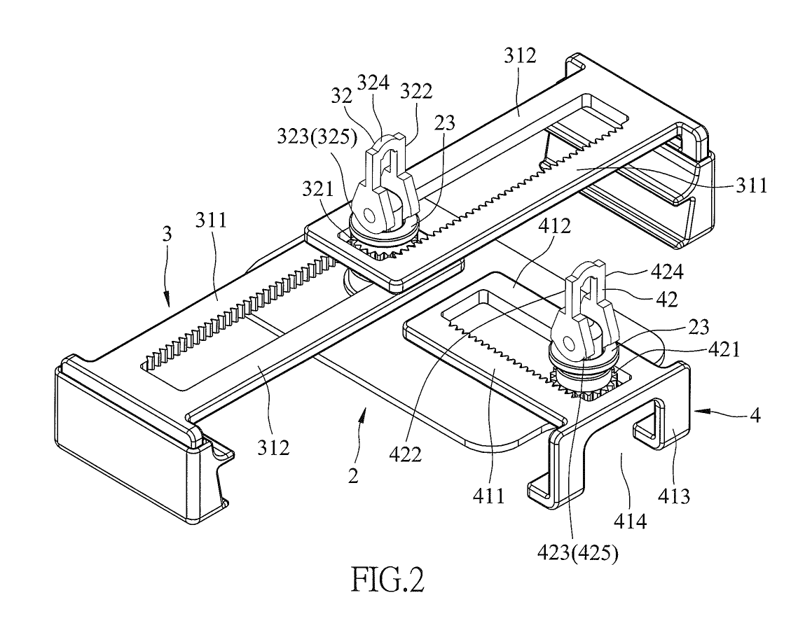

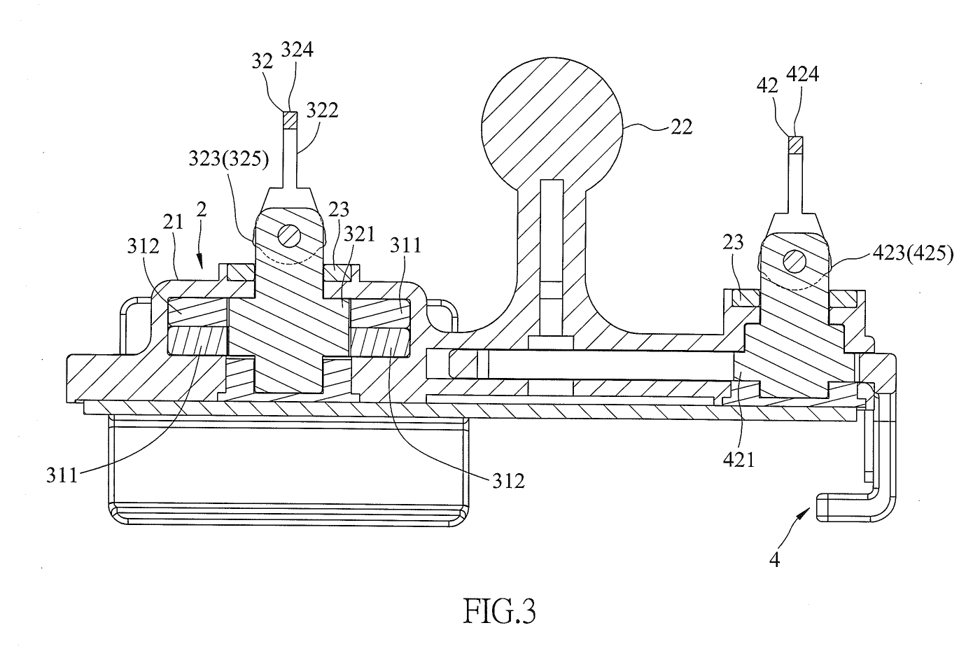

Referring to the drawings and initially to FIGS. 1-3, a support device for a tablet personal computer in accordance with the preferred embodiment of the present invention comprises a base unit 2, a width adjustment unit 3, and a height adjustment unit 4.

The base unit 2 includes a main body 21, a connecting member 22, and two antiskid pads 23. The connecting member 22 extends rearward from a rear side of the main body 21 and has a distal end formed with a spherical connecting head 221.

The width adjustment unit 3 includes two supporting modules 31 mounted on the base unit 2, and a width adjustment module 32 mounted on the base unit 2.

The supporting modules 31 are respectively extended rightward and leftward from the base unit 2 and overlap each other. Each of the supporting modules 31 includes a toothed rack 311 extended through the base unit 2, a guide track 312 located opposite to the toothed rack 311, and a holder 313 mounted on an outer end of the toothed rack 311. The toothed racks 311 of the supporting modules 31 are arranged in a stagger manner and are located opposite to each other. The toothed racks 311 of the supporting modules 31 are respectively extended rightward and leftward from the base unit 2. The guide track 312 of each of the supporting modules 31 is extended from the holder 313 toward the base unit 2 and extended through the base unit 2.

The width adjustment module 32 includes a width adjustment gear 321 arranged between the toothed racks 311 of the supporting modules 31 and respectively meshing with the toothed racks 311 of the supporting modules 31. The width adjustment gear 321 has two opposite sides respectively abutting the toothed rack 311 and the guide track 312 of each of the supporting modules 31. The width adjustment gear 321 is rotatable to drive the supporting modules 31 simultaneously to approach each other or to space from each other.

The width adjustment module 32 further includes a width adjustment fastener 322. The width adjustment fastener 322 has an abutting portion 323 mounted on the width adjustment gear 321, and a driving handle 324 mounted on the abutting portion 323. The driving handle 324 is driven to rotate about an axis thereof so as to drive and rotate the width adjustment gear 321. The abutting portion 323 has a projection 325. Thus, when the driving handle 324 is driven and pressed downward to approach the base unit 2, the projection 325 presses one of the antiskid pads 23 to increase the friction of the width adjustment fastener 322 so as to prevent the width adjustment fastener 322 from being swiveled easily, so that the width adjustment gear 321 is positioned and cannot be swiveled.

In the preferred embodiment of the present invention, the width adjustment fastener 322 has a substantially U-shaped cross-sectional profile and has two opposite ends pivotally mounted on the width adjustment gear 321. Each of the two opposite ends of the width adjustment fastener 322 has two enlarged opposite sides, so that when the abutting portion 323 is driven toward any one of the two enlarged opposite sides of the width adjustment fastener 322, the projection 325 can be moved to press one of the antiskid pads 23.

The height adjustment unit 4 includes a lower supporting module 41 mounted on the base unit 2 and extended downward, and a height adjustment module 42 mounted on the base unit 2.

The lower supporting module 41 includes a lower toothed rack 411 extended through the base unit 2 and extended downward, a lower guide track 412 located opposite to the lower toothed rack 411, and a lower holder 413 mounted on a lower end of the lower toothed rack 411. The lower guide track 412 of the lower supporting module 41 is extended from the lower holder 413 toward the base unit 2 and extended through the base unit 2. The lower holder 413 of the lower supporting module 41 has a middle portion provided with an opening 414.

The height adjustment module 42 includes a height adjustment gear 421 meshing with the lower toothed rack 411 of the lower supporting module 41. The height adjustment gear 421 has two opposite sides respectively abutting the lower toothed rack 411 and the lower guide track 412 of the lower supporting module 41. The height adjustment gear 421 is rotatable to drive the lower supporting module 41 to approach the base unit 2 or to space from the base unit 2.

The height adjustment module 42 further includes a height adjustment fastener 422. The height adjustment fastener 422 has an abutting portion 423 mounted on the height adjustment gear 421, and a driving handle 424 mounted on the abutting portion 423. The driving handle 424 is driven to rotate about an axis thereof so as to drive and rotate the height adjustment gear 421. The abutting portion 423 has a projection 425. Thus, when the driving handle 424 is driven and pressed downward to approach the base unit 2, the projection 425 presses the other one of the antiskid pads 23 to increase the friction of the height adjustment fastener 422 so as to prevent the height adjustment fastener 422 from being swiveled easily, so that the height adjustment gear 421 is positioned and cannot be swiveled.

In the preferred embodiment of the present invention, the height adjustment fastener 422 has a substantially U-shaped cross-sectional profile and has two opposite ends pivotally mounted on the height adjustment gear 421. Each of the two opposite ends of the height adjustment fastener 422 has two enlarged opposite sides, so that when the abutting portion 423 is driven toward any one of the two enlarged opposite sides of the height adjustment fastener 422, the projection 425 can be moved to press the other one of the antiskid pads 23.

In operation, when the driving handle 324 of the width adjustment fastener 322 is rotated, the width adjustment gear 321 is driven and rotated. At this time, the width adjustment gear 321 meshes with the toothed racks 311 of the supporting modules 31, so that when the width adjustment gear 321 is rotated, the supporting modules 31 are driven by the width adjustment gear 321 simultaneously to approach each other or to space from each other, so as to adjust the required width (the distance between the holders 313 of the supporting modules 31) rapidly. Then, the driving handle 324 of the width adjustment fastener 322 is driven and pressed downward to approach the base unit 2, so that the projection 325 presses one of the antiskid pads 23 as shown in FIG. 1 to increase the friction of the width adjustment fastener 322 so as to prevent the width adjustment fastener 322 from being swiveled easily, so that the width adjustment gear 321 is positioned and cannot be swiveled.

On the other hand, when the driving handle 424 of the height adjustment fastener 422 is rotated, the height adjustment gear 421 is driven and rotated. At this time, the height adjustment gear 421 meshes with the lower toothed rack 411 of the lower supporting module 41, so that when the height adjustment gear 421 is rotated, the lower supporting module 41 is driven by the height adjustment gear 421 to approach the base unit 2 or to space from the base unit 2, so as to adjust the required height (the distance between the lower holder 413 of the lower supporting module 41 and the base unit 2) rapidly. Then, the driving handle 424 of the height adjustment fastener 422 is driven and pressed downward to approach the base unit 2, so that the projection 425 presses the other one of the antiskid pads 23 as shown in FIG. 1 to increase the friction of the height adjustment fastener 422 so as to prevent the height adjustment fastener 422 from being swiveled easily, so that the height adjustment gear 421 is positioned and cannot be swiveled.

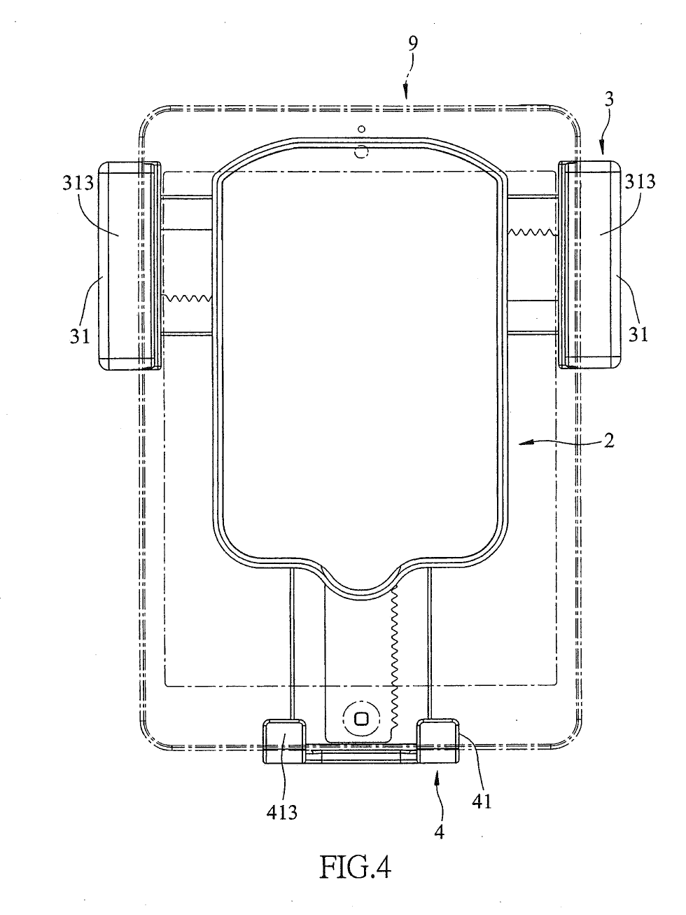

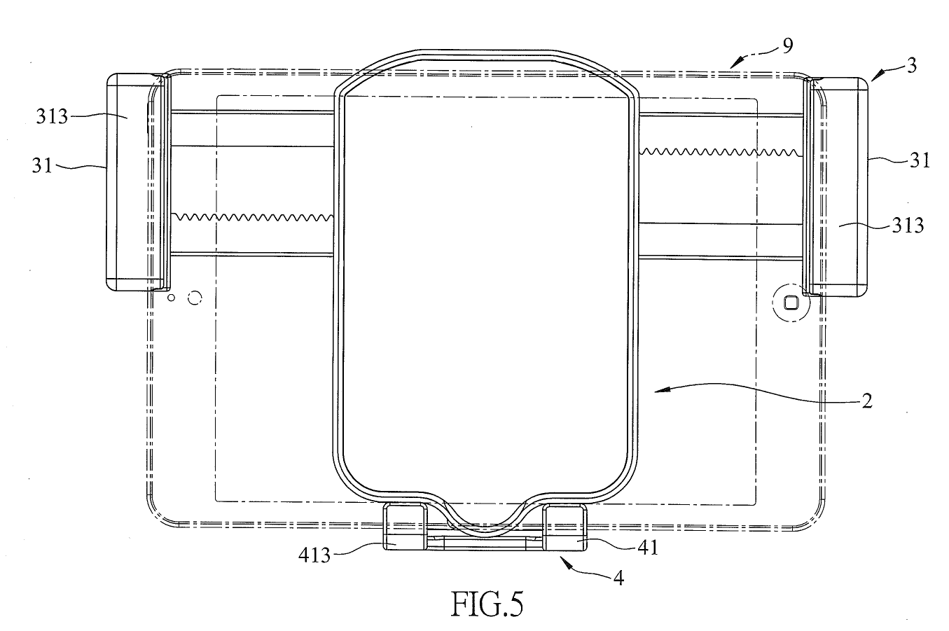

In practice, referring to FIGS. 4 and 5 with reference to FIGS. 1-3, a tablet personal computer 9 is placed on the base unit 2 and clamped between the holders 313 of the supporting modules 31 and the lower holder 413 of the lower supporting module 41. At this time, the width adjustment unit 3 is adjusted to fit the width of the tablet personal computer 9, and the height adjustment unit 4 is adjusted to fit the height of the tablet personal computer 9. In addition, the width adjustment unit 3 and the height adjustment unit 4 are positioned by the width adjustment fastener 322 and the height adjustment fastener 422.

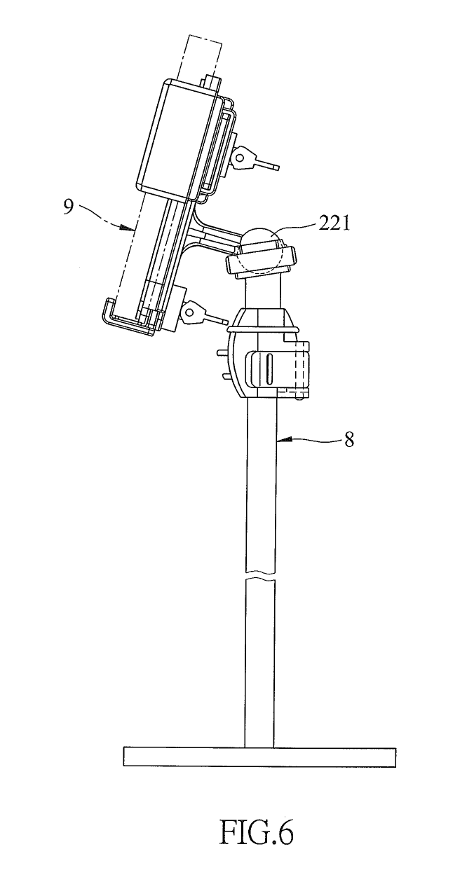

As shown in FIG. 6, the spherical connecting head 221 is mounted on an upright stand 8 so that the tablet personal computer 9 is supported by the upright stand 8.

Accordingly, the width adjustment gear 321 meshes with the toothed racks 311 so that when the width adjustment gear 321 is rotated, the supporting modules 31 are driven by the width adjustment gear 321 simultaneously to approach each other or to space from each other, so as to adjust the required width rapidly. In addition, the height adjustment gear 421 meshes with the lower toothed rack 411 so that when the height adjustment gear 421 is rotated, the lower supporting module 41 is driven by the height adjustment gear 421 to approach the base unit 2 or to space from the base unit 2, so as to adjust the required height rapidly. Further, the width adjustment unit 3 is adjusted freely to fit the width of the tablet personal computer 9, and the height adjustment unit 4 is adjusted freely to fit the height of the tablet personal computer 9, so that the support device is available for tablet personal computers of different sizes. Further, the tablet personal computer 9 is clamped between the holders 313 of the supporting modules 31 and the lower holder 413 of the lower supporting module 41 by positioning of the width adjustment fastener 322 and the height adjustment fastener 422. Further, the lower holder 413 of the lower supporting module 41 is provided with an opening 414 to prevent the slots of the tablet personal computer 9 from being hindered or blocked.

Although the invention has been explained in relation to its preferred embodiment(s) as mentioned above, it is to be understood that many other possible modifications and variations can be made without departing from the scope of the present invention. It is, therefore, contemplated that the appended claim or claims will cover such modifications and variations that fall within the true scope of the invention.

1. A support device for a tablet personal computer, comprising:
a base unit; and
a width adjustment unit; wherein:
the width adjustment unit includes:
two supporting modules mounted on the base unit; and
a width adjustment module mounted on the base unit;
the supporting modules are respectively extended rightward and leftward from the base unit;
each of the supporting modules includes:
a toothed rack extended through the base unit; and
a holder mounted on an outer end of the toothed rack;
the width adjustment module includes:
a width adjustment gear arranged between the toothed racks of the supporting modules and respectively meshing with the toothed racks of the supporting modules; and
the width adjustment gear is rotatable to drive the supporting modules simultaneously to approach each other or to space from each other.

2. The support device for a tablet personal computer of claim 1, wherein:
the toothed racks of the supporting modules are arranged in a stagger manner and are located opposite to each other;
the toothed racks of the supporting modules are respectively extended rightward and leftward from the base unit;
each of the supporting modules further includes a guide track located opposite to the toothed rack;
the guide track of each of the supporting modules is extended from the holder toward the base unit and extended through the base unit;
the width adjustment gear has two opposite sides respectively abutting the toothed rack and the guide track of each of the supporting modules.

3. The support device for a tablet personal computer of claim 2, wherein:
the width adjustment module further includes a width adjustment fastener;
the width adjustment fastener has an abutting portion mounted on the width adjustment gear, and a driving handle mounted on the abutting portion; and
the driving handle is driven to rotate about an axis thereof so as to drive and rotate the width adjustment gear.

4. The support device for a tablet personal computer of claim 3, wherein:
the abutting portion has a projection; and
when the driving handle is driven and pressed downward to approach the base unit, the projection presses the base unit to position the width adjustment fastener.

5. The support device for a tablet personal computer of claim 1, wherein:
the support device further comprises a height adjustment unit;
the height adjustment unit includes:
a lower supporting module mounted on the base unit and extended downward; and
a height adjustment module mounted on the base unit;
the lower supporting module includes:
a lower toothed rack extended through the base unit and extended downward; and
a lower holder mounted on a lower end of the lower toothed rack;
the height adjustment module includes a height adjustment gear meshing with the lower toothed rack of the lower supporting module; and
the height adjustment gear is rotatable to drive the lower supporting module to approach the base unit or to space from the base unit.

6. The support device for a tablet personal computer of claim 5, wherein:
the lower supporting module further includes a lower guide track located opposite to the lower toothed rack;
the lower guide track of the lower supporting module is extended from the lower holder toward the base unit and extended through the base unit; and
the height adjustment gear has two opposite sides respectively abutting the lower toothed rack and the lower guide track of the lower supporting module.

7. The support device for a tablet personal computer of claim 6, wherein:
the height adjustment module further includes a height adjustment fastener;
the height adjustment fastener has an abutting portion mounted on the height adjustment gear, and a driving handle mounted on the abutting portion; and
the driving handle is driven to rotate about an axis thereof so as to drive and rotate the height adjustment gear.

8. The support device for a tablet personal computer of claim 7, wherein:
the abutting portion has a projection; and
when the driving handle is driven and pressed downward to approach the base unit, the projection presses the base unit to position the height adjustment fastener.

9. The support device for a tablet personal computer of claim 8, wherein the lower holder of the lower supporting module has a middle portion provided with an opening.

10. The support device for a tablet personal computer of claim 9, wherein:
the base unit includes:
a main body; and
a connecting member; and
the connecting member extends rearward from a rear side of the main body and has a distal end formed with a spherical connecting head.
